(19) United States
(12) Patent Application Publication
(10) Pub. No.: US 2010/0117231 A1
(43) Pub. Date: May 13, 2010

(54) RELIABLE WAFER-LEVEL CHIP-SCALE SOLDER BUMP STRUCTURE

(76) Inventors: Dennis Lang, San Jose, CA (US); Sonbol Vaziri, Salt Lake City, UT (US); James Kent Naylor, Kaysville, UT (US); Eric Woolsey, Salt Lake City, UT (US); Chung-Lin Wu, San Jose, CA (US); Mike Gruenhagen, Salt Lake City, UT (US); Neill Thornton, Corvallis, OR (US)

Correspondence Address: HISCOCK & BARCLAY, LLP, 2000 HSBC PLAZA, 100 Chestnut Street, ROCHESTER, NY, 14604-2404, US

(21) Appl. No.: 12/690,179

(22) Filed: Jan. 20, 2010

Related U.S. Application Data
(63) Continuation-in-part of application No. 11/847,512, filed on Aug. 30, 2007, now abandoned.
(60) Provisional application No. 60/841,100, filed on Aug. 30, 2006.

(51) Int. Cl. H01L 23/498

(52) U.S. Cl. 257/738; 257/E23.07

(57) ABSTRACT

A wafer level chip scale package (WLCSP) includes a semiconductor device with a plurality of solder bump pads, patterned passivation regions above each of the solder bump pads, a patterned under bump metallization (UBM) region on each of the solder bump pads and the passivation regions, a polyimide region over a portion of the UBM regions and the passivation regions, solder bumps formed on each of the UBM regions.

### CROSS-REFERENCE TO RELATED APPLICATIONS

This application is a continuation-in-part of co-pending U.S. patent application Ser. No. 11/847,512 which claims the benefit of U.S. Provisional Patent Application Ser. No. 60/841,100, filed Aug. 30, 2006. The content of the aforementioned applications is hereby incorporated by reference.

### FIELD OF THE INVENTION

This invention relates to semiconductor fabrication, and more specifically to a method for fabricating solder bumped wafer-level chip-scale packages (WLCSPs).

### BACKGROUND OF THE INVENTION

WLCSPs generally use a metal layer to redistribute very fine-pitch peripheral-arrayed pads on a chip to much larger pitch area-arrayed pads with tall solder joints on the substrate. As a result, solder joint reliability is one of the most critical issues faced during WLCSP fabrication. The present invention is directed toward a new and high-throughput process for assembling WLCSPs on a substrate featuring highly reliable solder joints and protection from moisture penetration.

There exists a number of U.S. patents directed to improving the reliability of WLCSPs, including U.S. Pat. No. 6,287,893 issued to Elenius, et al. Elenius teaches a chip scale package design for a flip chip integrated circuit includes a redistribution metal layer upon the upper surface of a semiconductor wafer for simultaneously forming solder bump pads as well as the metal redistribution traces that electrically couple such solder bump pads with the conductive bond pads of the underlying integrated circuit. A patterned passivation layer is applied over the redistribution metal layer. Relatively large, ductile solder balls are placed on the solder bump pads for mounting the chip scale package to a circuit board or other substrate without the need for an underfill material. Elenius teaches the use of only one, non-conducting layer to cover redistribution lines.

U.S. Pat. No. 6,821,876 issued to Yang, et al. teaches a fabrication method for strengthening flip-chip solder bumps to form a solder bump on a UBM (under bump metallurgy) structure formed over a semiconductor chip, which can prevent the UBM structure against oxidation and contamination and also enhance bondability between the solder bump and UBM structure. This fabrication method is characterized in that before forming the solder bump, a dielectric layer made of BCB (benzo-cyclo-butene) or polyimide is deposited on the UBM structure, and used to protect the UBM structure against oxidation and contamination. Further, before forming the solder bump, a plasma-etching process is performed to remove the dielectric layer. Yang does not teach a fabrication process that includes non-conductive layers in the final structure.

A process for fabricating reliable solder bumped wafer-level chip-scale structures where the bumps exhibit superior adhesion to the die, minimal resistance, and improved protection from moisture penetration is desired in the art.

### SUMMARY OF THE INVENTION

The invention comprises, in one form thereof, a semiconductor device including a semiconductor die having at least one conductive bond pad formed upon a surface of the semiconductor die and a patterned first metallization layer disposed above the surface which provides at least one solder bump pad upon the surface, and electrically couples the at least one conductive bond pad to the at least one solder bump pad. The device also includes a patterned first non-conductive layer above first metallization layer, a patterned under bump metallization (UBM) layer above the first metallization layer and the first non-conductive layer, and a patterned second non-conductive layer over the front surface of the semiconductor wafer and above each of the first metallization layer, the first non-conductive layer, and the UBM layer. The device further includes a solder ball connection elements formed on each region of the UBM layer.

The invention further comprises, in one form thereof, a method of fabricating a semiconductor by forming a first metallization layer on a surface of a semiconductor wafer, selectively removing portions of the first metallization layer to provide a plurality of solder bump pads. Then forming a like plurality of first non-conductive regions over each of the plurality of solder bump pads, each of the first non-conductive regions having openings to a portion of a corresponding one of the solder bump pads, forming under bump metallurgical (UBM) regions over each of the openings and over a portion of a corresponding one of the first non-conductive regions, and forming a like plurality of second non-conductive regions over at least a portion of each of the first non-conductive regions, and over an outer portion of each of the UBM regions. Then forming solder balls above each of the solder bump pads, and dicing the semiconductor wafer to provide individual integrated circuits.

### BRIEF DESCRIPTION OF THE DRAWINGS

The aforementioned and other features, characteristics, advantages, and the invention in general will be better understood from the following more detailed description taken in conjunction with the accompanying drawings, in which:

FIG. 1 is a diagrammatical view of a first embodiment of a WLCSP solder bump structure according to the present invention;

FIG. 2 is a diagrammatical view of a second embodiment of a WLCSP solder bump structure according to the present invention;

FIG. 3A is a graphic representation of an edge of a solder ball wetting under an edge of a polyimide layer;

FIG. 3B is a line drawing of FIG. 3A;

FIG. 4 is a diagrammatical view of a third embodiment of a WLCSP solder bump structure according to the present invention;

FIG. 5 is a diagrammatical view of a fourth embodiment of a WLCSP solder bump structure according to the present invention;

FIG. 6 is a diagrammatical view of a fifth embodiment of a WLCSP solder bump structure according to the present invention; and

FIG. 7 is a partial side view of a WLCSP solder bump structure according to the present invention.

It will be appreciated that for purposes of clarity and where deemed appropriate, reference numerals have been repeated in the figures to indicate corresponding features.

Also, the relative size of various objects in the drawings has in some cases been distorted to more clearly show the invention.

### DETAILED DESCRIPTION

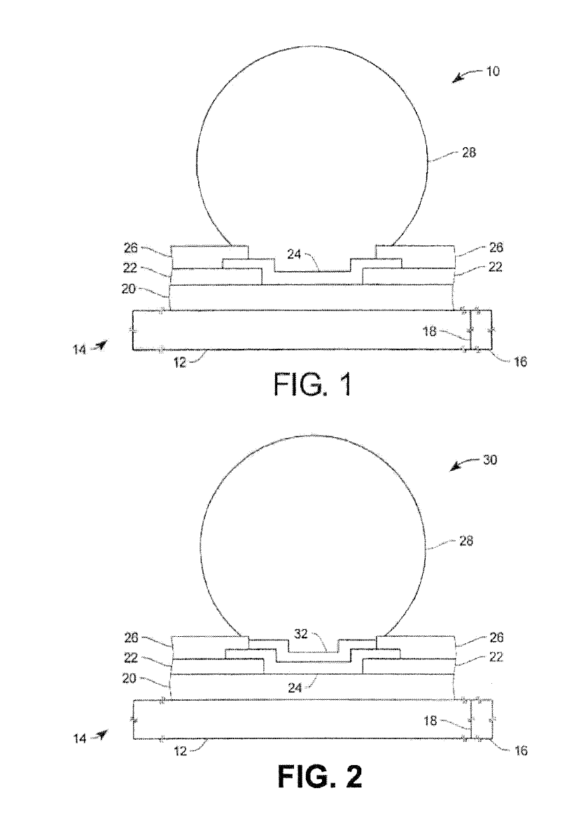

Referring to FIG. 1, there is shown a diagrammatical view of a first embodiment of a WLCSP solder bump structure 10 according to the present invention. The structure 10 is formed on a semiconductor die 12 which is part of a semiconductor wafer 14 when the structure 10 is formed. The semiconductor wafer 14 includes multiple semiconductor die including the semiconductor die 16 shown in FIG. 1. A wafer scribe line 18 lies between the semiconductor die 12, 16. The solder bump structure 10 includes a first metallization layer 20, a first non-conductive layer 22, a second metallization layer or under bump metallurgical (UBM) layer 24, a second non-conductive layer 26, and a solder bump 28. The first metallization layer 20 is typically a redistribution layer.

The WLCSP solder bump structure 10 may be formed by first depositing the top metallization layer 20, then masking and etching the layer to form the desired metallization pattern. The top metallization layer 20 (which may sometimes be considered a seed layer) may be aluminum or other metals. The top metallization layer 20 is then coated with a first non-conductive layer applied over the front (top) surface of semiconductor wafer 14. The first non-conductive layer (which may sometimes be considered a passivation layer) may be comprised of polyimide, BCB, silicon dioxide, silicon nitride, or other materials known to those skilled in the art. The first non-conductive layer is then patterned to form the first non-conductive layer 22 which allows access to first metal layer 20. Conventional photolithography techniques may be used to form the patterned openings.

The wafer 14 with aluminum layer 20 and first non-conductive layer 22 is then coated with UBM metallization which will form the UBM layer 24. In one embodiment of the present invention, this layer is formed by sputtering onto the wafer 14 between 1000 and 2400 angstroms of Ti followed by between 500 and 3300 angstroms of Ni. This Ti—Ni metallization layer is then masked or etched in one photo process to leave the UBM layer 24 partially covering the first metallization layer 20, and partially overlapping onto the first non-conductive passivation layer 22.

This UBM layer 24 may be a double or triple-metal stack. Other metals which may be used for the UBM layer 24 besides Ti—Ni include, but are not limited to, combinations of Ti, Ni, Au, Cu, or V. For example: Ti—Ni—Au, Ti—Ni—Cu, Ti—Ni—Cu—Au, Al, TiW—Al, Ti—Al, Ti—TiW—Al, Ti—Cu, Ti—Ni—Ag, Ni—V, TiW—Ni—Cu, or Ti—Ni—V. The selected metal(s) should have good adhesion to the first metallization layer 20. The UBM layer 24 serves one or more of the following purposes: (a) it adheres to the underlying surfaces; (b) it acts as a solder diffusion barrier for inhibiting molten solder from passing into the front surface of semiconductor wafer 14; (c) it serves as a “wettable” layer for solderability purposes; and (d) it serves to minimize electrical contact resistance between the solder ball 28 and the conductive bond pad.

The wafer 14 is then coated with a second non-conductive layer. In one embodiment of the invention the second non-conductive layer is of 1 to 6 microns in thickness, and may be polyimide, BCB, silicon dioxide, silicon nitride, or other materials known to those skilled in the art. Contact openings in this second non-conductive layer are made in one photo step by either etching or photo developing to form the second non-conductive layer 26. These openings overlap outer edge of the UBM layer 24, sealing the edge of the metal.

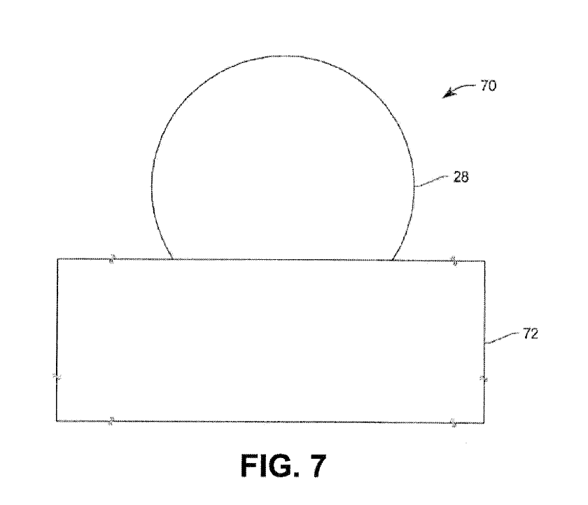

The stack now has metal contacts upon which the solder ball or bump 28 can be formed by several methods. These methods include, but are not limited to, screen printing solder paste/reflow, electro plating solder, or solder ball attach/reflow. After the wafer level chip scale structure is formed (as shown in FIG. 7), the solder bumps 28 can be soldered, brazed, thermocompression bonded, or ultrasonic bonded as with conventional solder bumps to another assembly such a printed circuit board or a lead frame.

FIG. 2 is a diagrammatical view of a second embodiment of a WLCSP solder bump structure 30 according to the present invention. In the embodiment shown in FIG. 2, the wafer 14 is placed in an electroless nickel plating process after the second non-conductive layer 26 is formed to deposit a low intrinsic stress electroless layer and then masked and etched to form the electroless nickel layer 32 only where the UBM layer 24 is exposed. The electroless nickel layer 32 shall be thick enough to separate the UBM layer 24 from metal deposits that will follow such as the solder bump 28.

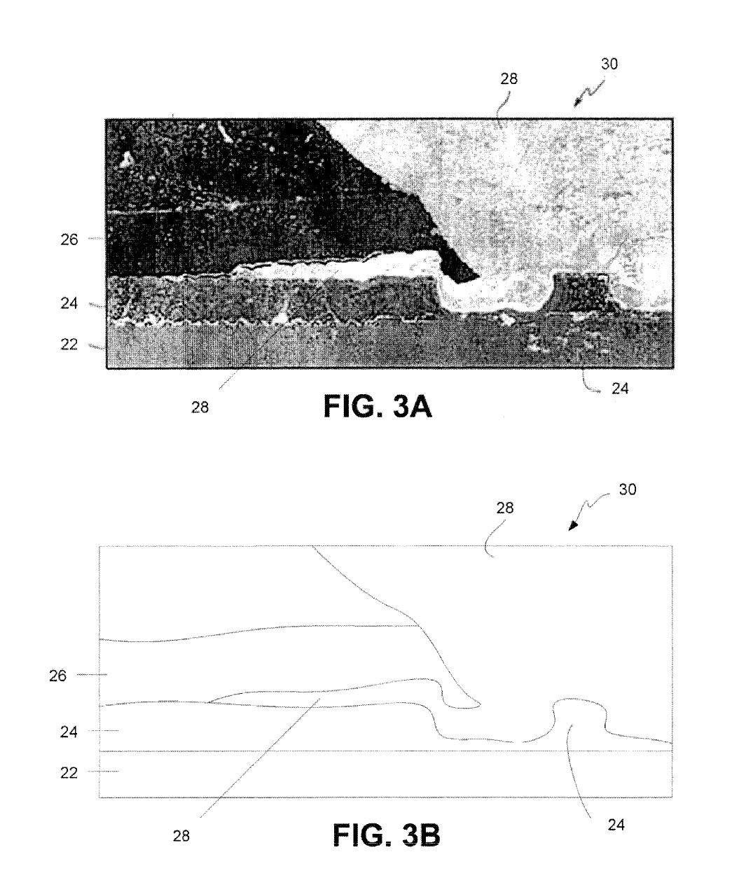

In the embodiment shown in FIG. 2 the electroless nickel layer 32 is thinner than the second non-conductive layer 26. In the embodiment of FIG. 1, electroless nickel layer 32 is absent. With the absent or thinner electroless nickel layer 32, the solder ball 28 attachment and reflow may result in some solder wetting under the second non-conductive layer 26 (in the case of polyimide) to consume some of the UBM layer 24. Some solder will also travel over the top of the UBM layer 24. The resultant structure will “lock” or “seal” the entire under bump structure from moisture penetration as shown in FIG. 3A and FIG. 3B. The embodiment shown in FIGS. 3A and 3B depicts the device of FIG. 1 after solder reflow.

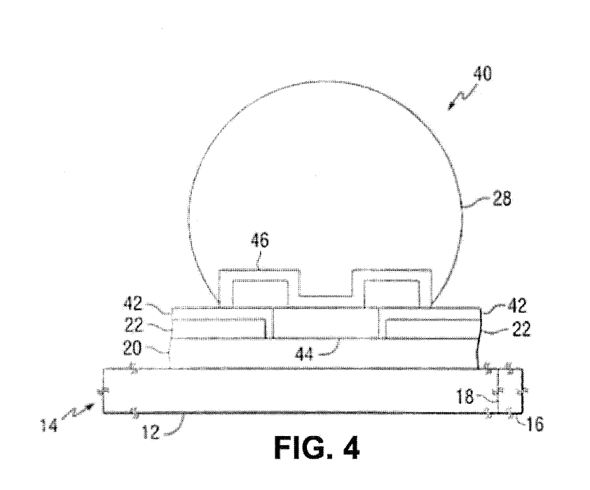

FIG. 4 is a diagrammatical view of a third embodiment of a WLCSP solder bump structure 40 according to the present invention. In FIG. 4, the periphery of the opening in the first non-conductive layer 22 is covered with a portion of the second non-conductive layer 42. Thus, a second metallization layer or UBM layer 44 is in contact with the first metallization layer 20 in an opening in the second non-conductive layer 42, but is not in contact with the first non-conductive layer 22. Also, the UBM layer 44 is thicker than the second non-conductive layer 42, and as a result the electroless nickel layer 46 will deposit on a portion of the top surface of the second non-conductive layer 42, making the coverage of the electroless nickel layer 46 larger than the opening in the second non-conductive layer 42. This overlapping electroless nickel layer 46 will promote adhesion of the second non-conductive layer 42 to the first metallization layer 20 below it, and provide additional protection from moisture penetration.

In practice, the covering of the first non-conductive layer 22 (which, in one or more embodiments, is polyimide) by the second non-conductive layer 42 followed by electroless nickel plating of the UBM layer 44 results in a thin first non-conductive layer 22 that is protected by the second non-conductive layer 42 from moisture penetration, and promotes adhesion of the UBM layer 44 to the wafer 14.

In the embodiment shown in FIG. 4 a stack including the silicon wafer 14, the first metallization layer 20, and the first non-conductive layer 22 is assembled as discussed heretofore. The second non-conductive layer is then deposited to cover the first non-conductive layer 22, and patterned to partially cover the first metallization layer 20. A polyimide layer is thereafter deposited, masked, and etched to form the second non-conductive layer 42. The second metallization layer is deposited and patterned to form the UBM layer 44 which partially overlaps the second non-conductive layer 42. The stack is then subjected to the electroless nickel plating process. The electroless Ni layer 46 is plated where the UBM layer 44 is exposed, and, as a result, partially on top of the second non-conductive layer 42. The stack is completed by solder ball 28 attachment as discussed above.

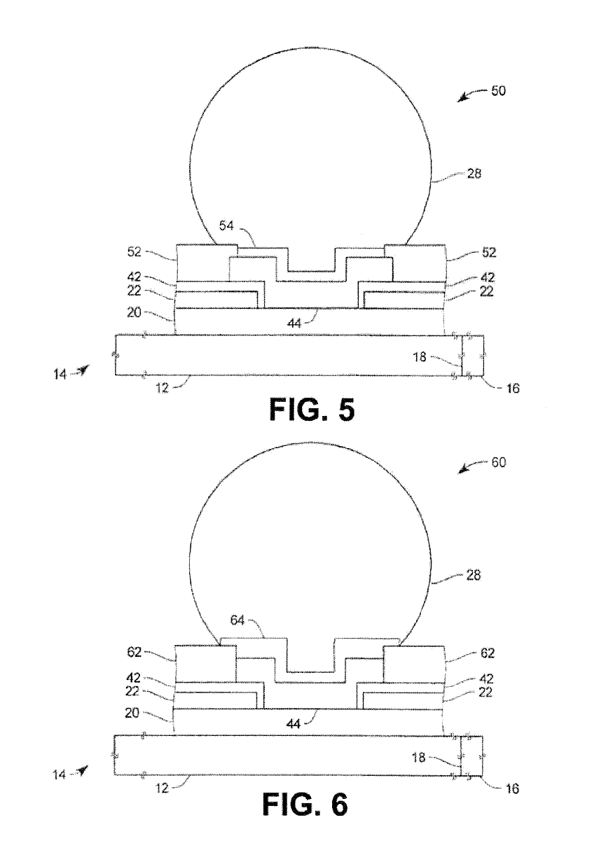

FIG. 5 is a diagrammatical view of a fourth embodiment of a WLCSP solder bump structure 50 according to the present invention. The embodiment of FIG. 5 includes the silicon wafer 14, the first metallization layer 20, the first non-conductive layer 22, the second non-conductive layer 42, and the UBM layer 44 shown in FIG. 4. A third non-conductive layer 52, which in one or more embodiments of the present invention is polyimide, and an electroless nickel plated layer 54 to form a stack. The solder bump 28 is formed on the stack. The first non-conductive layer 22, the second non-conductive layer 42, and the UBM layer 44 are assembled as discussed heretofore. The third non-conductive layer is then deposited, masked, and etched to form the third non-conductive layer 52 which at least partially overlaps the second conductive layer 42 and overlaps the periphery of the UBM layer 44. A thin electroless nickel layer is plated on top of UBM layer 44, only where UBM layer 44 is exposed to form the electroless nickel layer 54. The upper surface of the electroless nickel layer 54 is lower than the upper surface of the third non-conductive layer 52. The stack is completed by solder ball 28 attachment as discussed above.

FIG. 6 is a diagrammatical view of a fifth embodiment of a WLCSP solder bump structure 60 according to the present invention. FIG. 6 is similar to FIG. 5 except that in FIG. 6 the upper surface of the electroless nickel layer 64 is higher than the upper surface of a third non-conductive layer 62, and as a result the electroless nickel layer 64 will form on top of the inner periphery of the third non-conductive layer 62, making the electroless nickel area larger than the opening in the third non-conductive layer 62. This overlapping of electroless nickel layer 64 will promote adhesion of the third non-conductive layer 62 to the UBM layer 44 below it, and provide additional protection from moisture penetration. The stack is completed by solder ball 28 attachment as discussed above.

In alternative embodiments of the present invention an electroless gold layer may be used instead of the electroless nickel layers.

FIG. 7 is a partial side view of a WLCSP bump structure according to the present invention which contains a WLCSP solder bump structure according to an embodiment of the present invention. In one embodiment, not shown, the WLCSP is a component of a conventional encapsulated flip-chip semiconductor package.

While the invention has been described with reference to preferred embodiments, it will be understood by those skilled in the art that various changes may be made and equivalents may be substituted for elements thereof to adapt to particular situations without departing from the scope of the invention. Therefore, it is intended that the invention not be limited to the particular embodiments disclosed as the best mode contemplated for carrying out this invention, but that the invention will include all embodiments falling within the scope and spirit of the appended claims.

1-26. (canceled)

27. A wafer level chip scale semiconductor device comprising:
a semiconductor die having at least one conductive bond pad formed upon a surface of said semiconductor die;
a patterned first metallization layer disposed above said surface which provides at least one solder bump pad upon said surface, and electrically couples said at least one conductive bond pad to said at least one solder bump pad;
a patterned first non-conductive layer above first metallization layer;
a patterned under bump metallization (UBM) layer above said first metallization layer and said first non-conductive layer;
a patterned second non-conductive layer over the front surface of the semiconductor wafer and above each of said first metallization layer, said first non-conductive layer, and said UBM layer;
solder ball connection elements formed on each region of said UBM layer.

28. The semiconductor device of claim 27 wherein said UBM layer is plated with one of nickel and gold.

29. The semiconductor device of claim 27 wherein said semiconductor wafer comprises silicon.

30. The semiconductor device of claim 27 wherein at least one of said first and second non-conductive layers comprises silicon dioxide.

31. The semiconductor device of claim 27 wherein at least one of said first and second non-conductive regions comprises silicon nitride.

32. The semiconductor device of claim 27 wherein at least one of said first and second non-conductive layers comprises benzocyclobutene.

33. The semiconductor device of claim 27 wherein at least one of said first and second non-conductive layers comprises polyimide.

34. The semiconductor device of claim 27 wherein said UBM layer comprises titanium.

35. The semiconductor device of claim 27 wherein said UBM layer comprises copper.

36. The semiconductor device of claim 27 wherein said UBM layer comprises nickel.

37. The semiconductor device of claim 27 wherein said UBM layer is comprised of one or more of the group consisting of Ti, Ni, Au, Cu, and V.

38. The semiconductor device of claim 27 wherein said UBM layer is comprised of between 1000 and 2400 Angstroms of Ti and between 500 and 3300 Angstroms Ni.

39. The semiconductor device of claim 27 wherein said second non-conductive layer is from 1 to 6 microns in thickness.

40. (canceled)

41. The semiconductor device of claim 27, wherein solder from said solder ball is disposed between said second non-conductive layer and said UBM layer.
